(19) United States
(12) Patent Application Publication
(10) Pub. No.: US 2016/0071740 A1
(43) Pub. Date: Mar. 10, 2016

(54) PATTERN FORMING METHOD

(71) Applicant: KABUSHIKI KAISHA TOSHIBA, Tokyo (JP)

(72) Inventors: Katsuyoshi KODERA, Yokohama (JP); Yoshihiro Naka, Yokohama (JP)

(21) Appl. No.: 14/638,658

(22) Filed: Mar. 4, 2015

Related U.S. Application Data
(60) Provisional application No. 62/047,195, filed on Sep. 8, 2014.

(51) Int. Cl. H01L 21/311; G03F 7/36; H01L 21/027; G03F 7/20

(52) U.S. Cl. CPC H01L 21/31144; G03F 7/20; G03F 7/36; H01L 21/0271; H01L 21/31116

(57) ABSTRACT

A pattern forming method according to the present embodiment forms a self-assembly material layer including a liquid-crystal material in at least one block thereof on a surface of a base material. An external field in a first region of the self-assembly material layer is applied locally, the first region of the self-assembly material layer is rubbed locally, or a film thickness of the first region of the self-assembly material layer is changed locally. The self-assembly material layer is phase-separated.

### CROSS REFERENCE TO RELATED APPLICATIONS

This application is based upon and claims the benefit of priority from the prior U.S. Provisional Patent Application No. 62/047,195, filed on Sep. 8, 2014, the entire contents of which are incorporated herein by reference.

### FIELD

The embodiments of the present invention relate to a pattern forming method.

### BACKGROUND

In recent years, a lithography technique using a Self-Assembly (SA) material has been developed. The SA material is phase-separated into a spherical shape, a cylinder shape, or a lamellar shape according to the composition ratio of blocks of a polymer block copolymer. In the SA material, a dot pattern, a hole pattern, a pillar pattern, or a line pattern with various dimensions can be formed by adjusting its molecular weight.

A physical guise or a chemical guide is sometimes used in order to control the generation position of a phase separation structure having such various patterns.

However, even when such a guide is used, there are cases where the SA material cannot be formed in an intended pattern due to various reasons. That is, in the lithography technique using the SA material, the process margin for the orientation of the pattern is small, and thus there is a case where it is difficult to form the phase separation structure in a desired pattern.

### BRIEF DESCRIPTION OF THE DRAWINGS

FIGS. 1 to 7B are respectively a cross sectional view or a plan view showing an example of the pattern forming method according to the present embodiment; and

FIG. 8 shows an arrayed state of blocks having a cylinder structure.

### DETAILED DESCRIPTION

Embodiments will now be explained with reference to the accompanying drawings. The present invention is not limited to the embodiments.

A pattern forming method according to the present embodiment forms a self-assembly material layer including a liquid-crystal material in at least one block thereof on a surface of a base material. An external field in a first region of the self-assembly material layer is applied locally, the first region of the self-assembly material layer is rubbed locally, or a film thickness of the first region of the self-assembly material layer is changed locally. The self-assembly material layer is phase-separated.

A block polymer is constituted by elements (blocks) that are formed as a plurality (at least two) of monomers of the same type are continuously bonded to one another. The respective blocks are bonded to one another. That is, the block polymer is an element that is constituted by plural types of block-shaped and chemically-bonded polymers. By performing micro-phase separation due to repulsion between polymers of the block polymer, a fine periodic pattern is formed. The morphology of the block pattern, that is, a lamellar structure or a cylinder structure, is determined by the composition of the blocks. In this case, the block pattern is a pattern of a micro-phase separation structure (a block) that is formed when an SA material (a block copolymer) is phase-separated. For example, as a case of a block copolymer constituted by two types of polymers (a first polymer and a second polymer) is exemplified, when the ratio of the volume fraction between the two polymers is approximately 50%, the block pattern is formed in a lamellar structure. Meanwhile, when the ratio of these polymers is approximately 30%, the block pattern is formed in a cylinder structure. In the lamellar structure, the first polymer and the second polymer form layers alternately, and these polymers are alternately arrayed in the order of the first polymer, the second polymer, the first polymer, the second polymer, and onwards. Meanwhile, in the cylinder structure, one of the two polymers with a smaller ratio has a columnar morphology, and columns of the polymer are arranged periodically. The other one of the two polymers with a larger ratio is formed around the columns.

A guide pattern includes an orientation control layer that controls the orientation of the block polymer mentioned above and a pinning layer pattern that regularly arrays certain polymers in desired positions. The guide pattern has two types, that is, a chemical guide and a physical guide. In the case of the chemical guide, a pinning layer having a high affinity only with one of the two polymers in order to regularly array certain polymers in desired positions. In other positions where the pinning layer is not formed, the orientation control layer that controls the orientation of the block polymer is formed in order to control the orientation of the block polymer.

In the case of the physical guide, a structured body is formed. The affinity between a sidewall of the structured body and polymers is utilized. When the affinity between the sidewall of the structured body and one of the polymers is high, the one of the polymers is arranged in plural on the sidewall. Block polymers are regularly arrayed based on this arrangement. As for the orientation control of the block polymers, the orientation thereof is controlled by forming an orientation control layer on the bottom of the structured body.

The present embodiment can be applied to both cases of using the physical guide or the chemical guide, and can be also applied to cases where these guides are not used. In the following embodiment, explanations regarding the physical guide or the chemical guide are omitted.

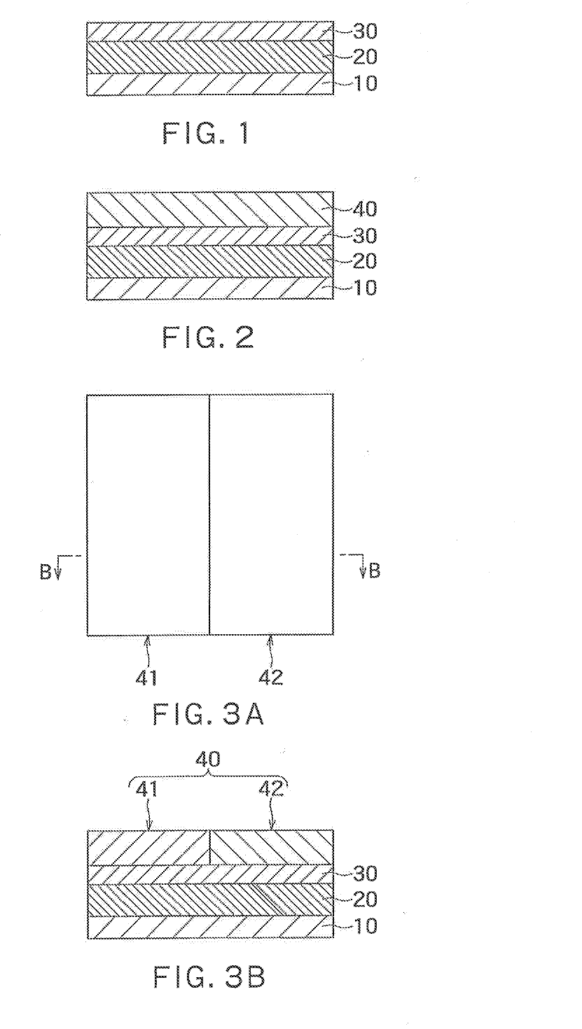

FIGS. 1 to 7B are respectively a cross sectional views or a plan view showing an example of the pattern forming method according to the present embodiment. FIGS. 3A, 5A, 6A, and 7A are cross sectional views and FIGS. 3B, 53, 63, and 7B are plan views.

First, as shown in FIG. 1, materials of a processing target film 20 and of a hard mask 30 are deposited on a substrate 10. In the present embodiment, the processing target film 20 and the hard mask 30 are base materials. When the substrate 10 is processed, the substrate 10 can be also included in the base materials. Although not limited thereto, the substrate 10 can be a silicon substrate, for example. Also, although not limited thereto, the material of the processing target film 20 can be a material such as polysilicon, silicon single crystal, or SOC (Spin On Carbon). The material of the hard mask 30 is preferably a material different from that of the processing target film 20 (that is, a material having an etching rate lower than that of the processing target film 20), and the material of the hard mask 30 is, for example, an insulation film such as a silicon oxide film (such as SCG (Spin On Glass)) or a silicon nitride film.

Next, as shown in FIG. 2, an SA material layer 40 is formed on the material of the hard mask 30. The SA material layer 40 includes a liquid-crystal material in at least one block thereof. For example, the SA material layer 40 is formed by using pEO-b-pMA (Az) (polyethylene oxide-b-polymethacrylate (azobenzene)), pEO is a hydrophilic block of polyethylene glycol, and pMA (Az) is a hydrophobic block of methacrylate including azobenzene (Az).

In the present embodiment, the SA material layer 40 includes Az (azobenzene) as its liquid crystal material. However, the liquid crystal material constituting the SA material is not limited to Az. As the liquid crystal material, instead of using Az, it is also possible to use a derivative such as biphenyl, benzoic acid, benzaldehyde, phenol, aniline, acetophenone, benzonitrile, 4-alkylcyclohexane carboxylic acid, or 4-alkyl bromobenzene. Furthermore, the liquid crystal material can be included, not just one of the block polymers of the SA material layer 40, in both of the block polymers.

As for the block polymers constituting the SA material, it is not limited to pEO (polyethylene oxide) or pMA (polymethacrylate). Instead of using pEO or pMA, these block polymers can use, for example, any of poly-n-butyl methacrylate (PnBMA), poly-t-butyl methacrylate (PtBMA), poly(hexafluoropropylene), polybutadiene, polycarbonate (PC), polychlorotrifluoroethylene (PCTFE), polydimethylsiloxane (PDMS), polyethylene (PE), polyethylene oxide (PEO), polyethylene glycol (PEG), polyethylene terephthalate (PET), polyisobutylene (PIB, Butyl rubber), polymethyl methacrylate (PMMA, acrylic, plexiglas), polyoxymethylene (POM, polyacetal, polymethylene oxide), polyphenylene sulfide (PPS), polypropylene (PP), polystyrene (PS), polysulfone (PSU), polytetrafluoroethylene (PTFE), polytrifluoroethylene, polyvinyl acetate (PVA), polyvinyl alcohol (PVOH), polyvinyl chloride (PVC), polyvinyl fluoride (PVF), polyvinylidene chloride (PVDC, Saran), or polyvinylidene fluoride (PVDF).

In order to locally change a part of the orientation direction of the SA material layer 40, an external field is applied in a part of the SA material layer 40, a rubbing process is performed locally in a part of the SA material layer 40, or the film thickness of a part of the SA material layer 40 is changed locally. In this case, the SA material layer 40 includes azobenzene (Az) as its liquid crystal material. Accordingly, by performing locally application of an external field, a rubbing process, or changing of the film thickness, the orientation direction of the SA material layer 40 can be changed locally.

For example, the orientation direction of a first region 41, which is the left half of the SA material layer 40, is changed without changing the orientation direction of a second region 42, which is the right half of the SA material layer 40. The positions of the first region 41 and the second region 42 are as shown in FIGS. 3A and 3B. FIG. 3B is a cross sectional view along a line B-B in FIG. 3A. In this case, in order to change the orientation direction of the liquid crystal material of the first region 41, application of an external field in the region 41 or a rubbing process in the region 41 is performed, or the film thickness of the SA material layer 40 in the first region 41 is made different from that of the region 42. Meanwhile, in the region 42, both application of an external field and a rubbing process are not performed.

In this case, the external field is light, an electric field, or a magnetic field, for example. When light is irradiated on the region 41 as an external field, for example, linearly-polarized light in a visible region is irradiated on the region 41. By the irradiation of linearly-polarized light, azobenzene (Az) of the SA material layer 40 in the region 41 selectively reacts to the irradiation according to the polarization direction of the linearly-polarized light, and the orientation direction in the region 41 changes. With this configuration, the orientation direction of the SA material layer 40 in the region 41 can be controlled while maintaining the orientation direction of the SA material layer 40 in the region 42.

When an electric field or a magnetic field is applied in the region 41 as an external field, the orientation direction of azobenzene (Az) of the SA material layer 40 in the region 41 changes. With this change, the orientation direction of the SA material layer 40 in the region 41 can be controlled while maintaining the orientation direction of the SA material layer 40 in the region 42.

When a rubbing process is performed in the region 41, the SA material layer 40 in the region 41 is rubbed in a certain direction with a roller having wrapped thereon a material such as nylon. By rubbing the SA material layer 40 in the region 41, the orientation direction of azobenzene (Az) of the SA material layer 40 in the region 41 changes. With this change, the orientation direction of the SA material layer 40 in the region 41 can be controlled while maintaining the orientation direction of the SA material layer 40 in the region 42.

Furthermore, the film thickness of the SA material layer 40 in the region 41 can be changed. Because each of block copolymers of the SA material layer 40 has a phase separation period, orientations of phase-separated block patterns are different depending on the thickness of the SA material layer 40. For example, pEO-b-pMA (Az) is phase-separated into one block having a cylinder structure and other blocks around the one block. In this case, as shown in FIG. 8, as viewed in a vertical cross section in an extending direction of the blocks having a cylinder structure, six blocks having a cylinder structure are positioned in a regular hexagonal shape. FIG. 8 shows an arrayed state of blocks having a cylinder structure. A distance between blocks that are linearly adjacent to each other in a D1 direction is assumed as a cylinder distance dcyl. Furthermore, the plurality of blocks arrayed in the D1 direction respectively constitute a lamellar surface Lam. A distance between lamellar surfaces Lam that are adjacent to each other in a vertical direction D2, which is vertical with respect to the D1 direction, is assumed as a lamellar distance dlam (dlam=dcyl×sin 60°).

A distance ds (not shown) between the hard mask layer 30 and blocks having cylinder structures become different when there is an affinity between the hard mask layer 30 and the blocks having a cylinder structure and when there is an affinity between the hard mask layer 30 and other blocks around the cylinder structures.

Assuming that a film thickness t of the SA material layer 40 satisfies the following Equation 1,

t=2×ds+n×dlam Equation 1

when the SA material layer 40 is phase-separated, the blocks having a cylinder structure become easier to be arrayed as these blocks extend in a substantially horizontal direction (a lateral direction) with respect to the surface of the hard mask 30.

On the other hand, when the film thickness t of the SA material layer 40 does not satisfy Equation 1, or when the thickness t is sufficiently large (for example, n is equal to or larger than 3), at the time of phase separating the SA material layer 40, the blocks having a cylinder structure become easier to be arrayed as these blocks extend in a substantially vertical direction (a longitudinal direction) with respect to the surface of the hard mask 30.

When the block copolymer is formed in a lamellar structure, arraying of the lamellar structure is changed depending on the affinity between the hard mask 30 and two blocks constituting the block copolymer and on the affinity between an air interface and two blocks constituting the block copolymer. For example, it is assumed here that the two blocks constituting the block copolymer is a block A and a block B, the air interface has a higher affinity with the block B as compared to the block A, and the hard mask 30 has a higher affinity with the block A as compared to the block B. At this time, the hard mask and the air interface has a respectively different affinity with respect to the two blocks A and B. In this case, when the film thickness of the SA material layer 40 takes an even multiple of a half (a half pitch) of the phase separation period, it becomes easier to perform phase separation on the SA material layer 40 such that the lamellar periodic direction becomes a substantially horizontal direction with respect to the surface of the hard mask 30. On the other hand, when the film thickness of the SA material layer 40 does not take an even multiple of a half (a half pitch) of the phase separation period, it becomes easier to perform phase separation on the SA material layer 40 such that the lamellar periodic direction extends in a substantially vertical direction with respect to the surface of the hard mask 30.

Meanwhile, there is also a case where both of the hard mask 30 and the air interface have a higher affinity with the same block (the block A, for example) as compared to the other block (the block B, for example). In this case, because both of the hard mask 30 and the air interface have an affinity to one of the two blocks A and B, when the film thickness of the SA material layer 40 is an odd multiple of a half (a half pitch) of the phase separation period, it becomes easier to perform phase separation on the SA material layer 40 such that the lamellar periodic direction becomes a substantially horizontal direction with respect to the surface of the hard mask 30. On the other hand, when the film thickness of the SA material layer 40 does not take an odd multiple of a half (a half pitch) of the phase separation period, it becomes easier to perform phase separation on the SA material layer 40 such that the lamellar periodic direction extends in a substantially vertical direction with respect to the surface of the hard mask 30.

In this manner, by setting the film thickness of the SA material layer 40 while taking the affinity between the hard mask 30 and respective blocks or that between the air interface and respective blocks into consideration, the block pattern after performing phase separation can be controlled.

Accordingly, the orientation direction of the SA material layer 40 in the region 41 can be controlled by changing the film thickness of the SA material layer 40 in the region 41.

It suffices that the film thickness of the SA material layer 40 is set with arrangement of steps on the surface of the hard mask 30 as a base material. For example, the hard mask 30 below the region 41 is formed relatively higher, and the hard mask 30 below the region 42 is formed relatively lower. When the SA material layer 40 is in a liquid form, the top surface of the SA material layer 40 becomes flat, in such a manner that the film thickness of the SA material layer 40 on the hard mask 30 becomes thin in the region 41 and becomes thick in the region 42.

Alternatively, it is also possible to change the film thickness of the SA material layer 40 by pressing a substrate (not shown) with steps on the surface of the SA material layer 40. The substrate with steps can be, for example, a silicon substrate on which a part thereof corresponding to the region 42 has been etched. In this case, in order to maintain the film thickness difference of the SA material layer 40, thermal treatment can be performed while the substrate is being pressed on the surface of the SA material layer 40.

When the orientation direction of the SA material layer 40 is changed, this changing can be made as two of more of application of an external field (such as light, an electric field, or a magnetic field), a rubbing process, and changing of the film thickness mentioned above are combined with each other.

As described above, in the present embodiment, it is possible to locally control the orientation direction of the SA material layer 40 in the region 41 while maintaining the orientation direction of the SA material layer 40 in the region 42. Accordingly, the orientation direction after performing phase separation on the SA material layer 40 can be made different between the region 41 and the region 42.

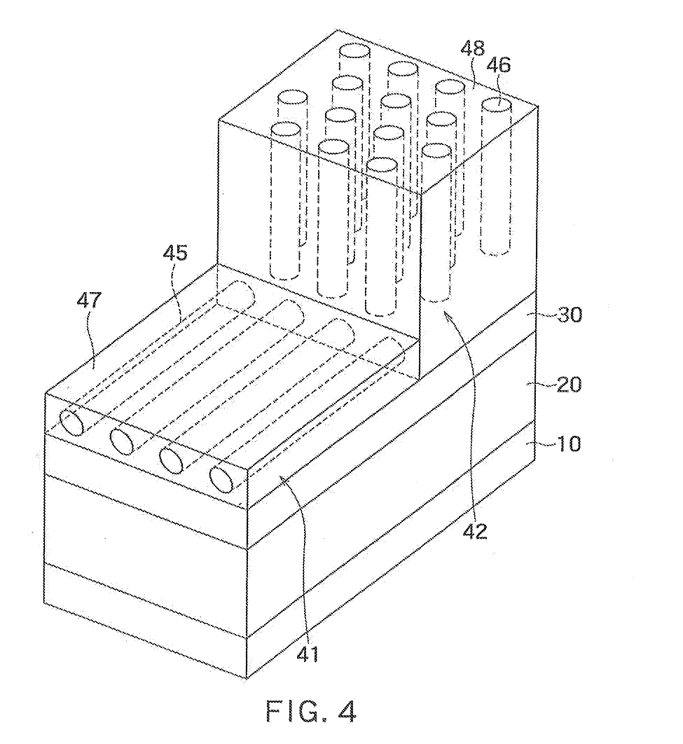

Next, in order to perform phase separation on the SA material layer 40, the SA material layer 40 is subjected to thermal treatment. The SA material layer 40 is phase-separated along with its orientation direction by this thermal treatment. For example, as shown in FIG. 4, the SA material layer 40 in the region 41 is phase-separated into a cylinder structure (a pEO layer) 45 extending in a substantially horizontal direction (a lateral direction) on the surface of the hard mask 30 and a pMA (Az) layer 47 provided around the cylinder structure 45. The SA material layer 40 in the region 42 is phase-separated into a cylinder structure (a pEO layer) 46 extending in a substantially vertical direction (a longitudinal direction) on the surface of the hard mask 30 and a pMA (Az) layer 48 provided around the cylinder structure 46. The cylinder structure 46 in the region 42 can be arranged to form a hexagon in a planar layout (that is, a hexagonal structure).

This thermal treatment step can be performed after controlling the orientation direction of the SA material layer 40, or can be performed simultaneously with the control of the orientation direction of the SA material layer 40. That is, the phase separation can be performed simultaneously with application of an external field, rubbing, or changing of the film thickness. In this case, the SA material layer 40 is phase-separated while its orientation direction is being controlled. With this process, it becomes much easier to locally change the phase-separation pattern of the SA material layer 40. Furthermore, because the thermal treatment step is performed simultaneously with the control of the orientation direction of the SA material layer 40, the time for a manufacturing step can be shortened.

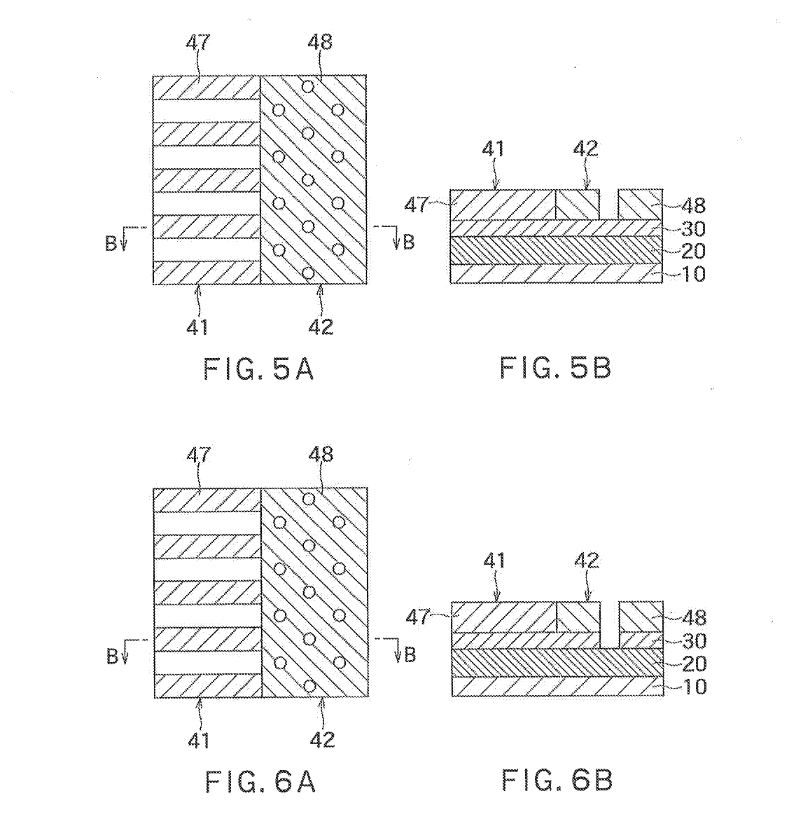

Next, the cylinder structures (pEO layers) 45 and 46 are selectively etched by using methods such as a CDE (Chemical Dry Etching) method or a wet etching method. As shown in FIG. 5A, with this etching step, in the region 41, the cylinder structure 45 as one of phase-separated structures arrayed in a lateral direction is removed, and a pMA (Az) layer 47 as the other one of the phase-separated structures is formed in a line-and-space pattern. In the region 42, the cylinder structure 46 as one of the phase-separated structures arrayed in a longitudinal direction is removed, and a pMA (Az) layer 48 as the other one of the phase-separated structures is formed in a hole pattern.

Next, the hard mask 30 is processed with an RIE (Reactive Ion Etching) method by using the pMA (Az) layers 47 and 48 as a mask. With this process, as shown in FIGS. 6A and 6B, patterns of the pMA (Az) layers 47 and 48 are respectively transferred on the hard mask 30.

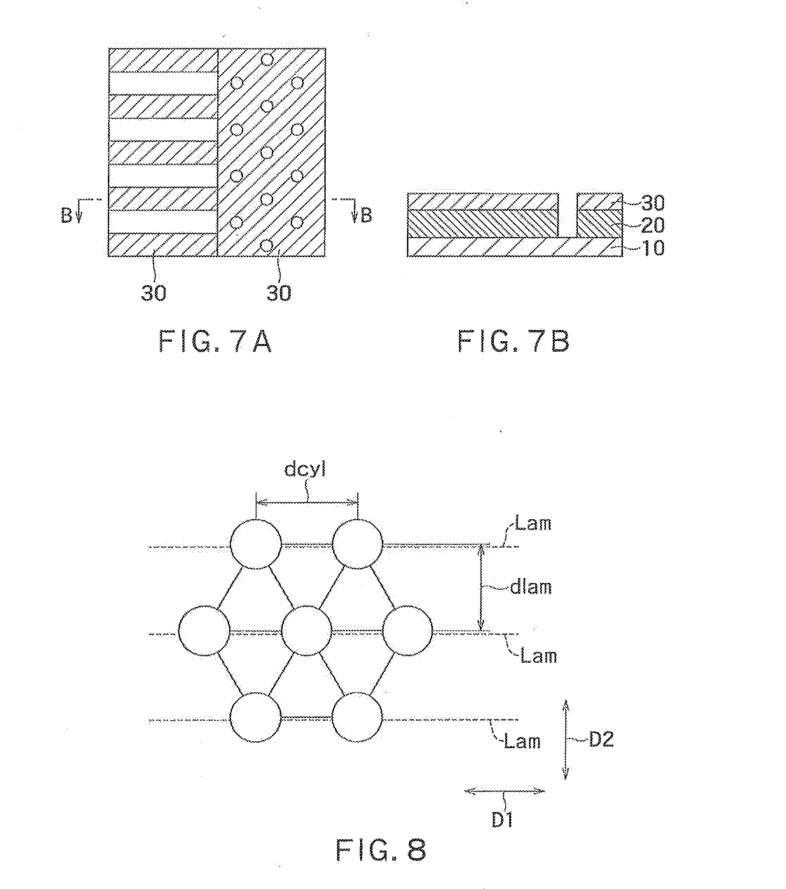

Next, after removing the pMA (Az) layers 47 and 48, the processing target film 20 is processed with the RIE method by using the hard mask 30 as a mask. With this process, as shown in FIGS. 7A and 7B, the line-and-space pattern of the pMA (Az) layer 47 and the hole pattern of the pMA (Az) layer 48 are transferred on the hard mask 30 and the processing target film 20. The line-and-space pattern formed on the processing target film 20 can be used for wires and the like. The hole pattern formed on the processing target film 20 can be used for contact holes, through-silicon vias, trench-gate electrodes and the like.

Thereafter, by forming an inter-layer dielectric film and a wire (both not shown), a semiconductor device can be formed. Note that the present embodiment can be also applied to various usages for forming fine structured bodies, as well as semiconductor devices. For example, the present embodiment can be also used for patterning an original plate of nanoimprint.

According to the present embodiment, by performing application of an external field or a rubbing process, or by locally controlling the film thickness of the SA material layer 40, the orientation direction of the SA material layer 40 can be made locally different. At this time, control of the orientation direction of the SA material layer 40 does not necessarily require a guide. Furthermore, the region in which the orientation direction of the SA material layer 40 is controlled can be determined by the region in which application of an external field or a rubbing process is performed or in which the film thickness of the SA material layer 40 is controlled. With this configuration, in the present embodiment, the phase separation structure of the SA material layer 40 can be variously changed for each region.

Furthermore, in the present embodiment, a guide pattern can be also used. By using a guide pattern, orientation control by the guide pattern and local orientation control according to the present embodiment can be combined with each other. In this case, not only by the guide pattern but also by application of an external field, a rubbing process, or changing of the thickness of the SA material layer 40, the orientation direction of the SA material layer 40 and the morphology of phase separation can be controlled locally and more finely. As a result, the freedom degree of the orientation of the SA material layer 40 is increased and the process margin for the orientation can be enlarged more than those of conventional techniques.

In the present embodiment, the SA material layer 40 that is phase-separated into a cylinder structure has been mainly explained. However, needless to mention, the present embodiment can be also applied to an SA material layer that is phase-separated into other types of block patterns such as a lamellar structure.

1. A pattern forming method comprising:
forming a self-assembly material layer including a liquid-crystal material in at least one block thereof on a surface of a base material;
locally applying an external field in a first region of the self-assembly material layer, locally rubbing in the first region of the self-assembly material layer, or locally changing a film thickness of the first region of the self-assembly material layer; and
phase-separating the self-assembly material layer.

2. The method of claim 1, wherein an orientation direction of the self-assembly material layer is different in the first region of the self-assembly material layer and in the second region of the self-assembly material layer.

3. The method of claim 1, wherein the external field is any one of light, an electric field, or a magnetic field.

4. The method of claim 2, wherein the external field is any one of light, an electric field, or a magnetic field.

5. The method of claim 1, wherein phase separation of the self-assembly material layer is performed almost simultaneously with the applying of the external field, the rubbing, or the changing of a film thickness.

6. The method of claim 2, wherein phase separation of the self-assembly material layer is performed almost simultaneously with the applying of the external field, the rubbing, or the changing of a film thickness.

7. The method of claim 3, wherein phase separation of the self-assembly material layer is performed almost simultaneously with the applying of the external field, the rubbing, or the changing of a film thickness.

8. The method of claim 1, wherein phase separation of the self-assembly material layer is performed by thermal treatment.

9. The method of claim 2, wherein phase separation of the self-assembly material layer is performed by thermal treatment.

10. The method of claim 3, wherein phase separation of the self-assembly material layer is performed by thermal treatment.

11. The method of claim 1, wherein
one of phase-separated structures of the phase-separated self-assembly material layer is phase-separated into a cylinder shape,
the one of phase-separated structures is phase-separated in the first region of the self assembly material layer so as to extend in a substantially horizontal direction with respect to the surface of the base material, and
the one of phase-separated structures is phase-separated in the second region of the self-assembly material layer so as to extend in a substantially vertical direction with respect to the surface of the base material.

12. The method of claim 2, wherein
one of phase-separated structures of the phase-separated self-assembly material layer is phase-separated into a cylinder shape,
the one of phase-separated structures is phase-separated in the first region of the self-assembly material layer so as to extend in a substantially horizontal direction with respect to the surface of the base material, and
the one of phase-separated structures is phase-separated in the second region of the self-assembly material layer so as to extend in a substantially vertical direction with respect to the surface of the base material.

13. The method of claim 11, further comprising selectively removing the one of the phase-separated structures of the phase-separated self-assembly material layer.

14. The method of claim 12, further comprising selectively removing the one of the phase-separated structures of the phase-separated self-assembly material layer.

15. The method of claim 13, further comprising processing the base material by using the other one of the phase-separated structures of the phase-separated self-assembly material layer as a mask.

16. The method of claim 14, further comprising processing the base material by using the other one of the phase-separated structures of the phase-separated self-assembly material layer as a mask.

17. The method of claim 15, wherein
in the first region, the base material is processed in a line-and-space pattern, and
in the second region, the base material is processed in a hole pattern.

18. The method of claim 16, wherein
in the first region, the base material is processed in a line-and-space pattern, and
in the second region, the base material is processed in a hole pattern.

19. The method of claim 1, wherein the self-assembly material layer is formed by using pEO-b-pMA(Az).

20. The method of claim 1, wherein the liquid crystal material in the self-assembly material layer is any one of derivatives among azobenzene, biphenyl, benzoic add, benzaldehyde, phenol, aniline, acetophenone, benzonitrile, 4-alkylcyclohexane carboxylic acid, or 4-alkyl bromobenzene.
